(19) United States
(12) Patent Application Publication
(10) Pub. No.: US 2001/0055861 A1
(43) Pub. Date: Dec. 27, 2001

(54) Process for manufacturing deep well junction structures

(76) Inventors: Davide Patti, Catania (IT); Cesare Ronsisvalle, San Giovanni La Punta (IT)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/825,143

(22) Filed: Apr. 3, 2001

(30) Foreign Application Priority Data
Apr. 4, 2000 (IT) T02000A000319

(51) Int. Cl. H01L 21/8238; H01L 21/425

(52) U.S. Cl. 438/524; 438/218; 438/223

(57) ABSTRACT

A process for manufacturing deep well junction structures that includes in succession, the steps of: on a first substrate having a first conductivity type and a first doping level, growing an epitaxial layer having the first conductivity type and a second doping level lower than the first doping level; anisotropically etching the epitaxial layer using a mask to form trenches; forming deep conductive regions surrounding the trenches and having a second conductivity type, opposite to the first conductivity type and the second doping level; and filling the trenches. The deep conductive regions are formed by angular ionic implantation and subsequent diffusion of a doping ion species within the epitaxial layer.

### TECHNICAL FIELD

The present invention relates to a process for manufacturing deep well junction structures.

### BACKGROUND OF THE INVENTION

As is known, a new type of junction structure, of the so-called deep well type, has been proposed, for forming MOS power transistors with a high inverse breakdown voltage, and simultaneously low resistance values. A junction structure of this type is described for example in U.S. Pat. No. 5,216,275 issued Jun. 1, 1993, according to which the junction structures with deep wells comprise a plurality of deep wells of doped semiconductor material, extending in an epitaxial layer downwards as far as close to a substrate, substantially parallel to one another. In particular, the deep wells have a prevalent vertical dimension (for example between 40 μm and 100 μm), and have an opposite conductivity to the epitaxial layer. When the junction structure is inversely biased, as the inverse voltage increases, the equipotential lines associated with two adjacent deep wells extend in the epitaxial layer, firstly parallel to the walls of the deep wells, and then join together so that the portions of epitaxial layer contained between the two adjacent deep wells are depleted.

The particular geometry of the junction structure gives rise to high inverse breakdown voltages even in the presence of quite high doping levels of the epitaxial layer and of the deep wells (approximately 10¹⁵ atoms/cm³).

At present, the described junction structures are formed according to two manufacturing processes.

In a first case, taught in the aforementioned patent, the epitaxial layer, for example of N type, is grown to a required thickness. Subsequently, trenches are formed in the epitaxial layer having a preset depth substantially equal to the conduction regions to be formed. Using a second epitaxial growth, the trenches are then filled with semiconductor material with an opposite conductivity to the epitaxial layer (for example P type conductivity), such as to form the deep wells substantially within the trenches.

However, the present technological limits in performing epitaxial growth processes make the step of filling the trenches problematic, and it does not yield acceptable results.

According to a different solution, the epitaxial layer and the deep wells are formed by iterating a sequence of process steps that involve partial epitaxial growth, a photo technique for defining the areas to be doped, and ionic implantation. For example, at each iteration, a partial epitaxial layer 20 μm thick is grown, and wells with an opposite conductivity are formed in the epitaxial layer. The wells extend throughout the thickness of the partial epitaxial layer, until corresponding aligned wells, formed in a previous iteration.

The described method allows forming junction structures wherein the deep well regions extend to a substantial depth (of as much as 100 μm, as already stated). However, in order to obtain this depth, it is necessary to carry out numerous cycles of epitaxial growth, photo technique and ionic implantation, and this is disadvantageously complex and costly.

### SUMMARY OF THE INVENTION

The embodiment of the present invention provides a process for manufacturing deep well junction structures, which overcomes the described disadvantages.

According to the present invention, a process for manufacturing deep well junction structures is provided, the process including forming trenches in a semiconductor material body and forming deep conductive regions surrounding the trenches and having a second conductivity type opposite to the conductivity type of the semiconductor material body, the deep conductive regions extending from the trenches towards the interior of the semiconductor material body, and implanting a doping species along directions inclined with respect to a perpendicular to a surface of a semiconductor material body.

In accordance with another aspect of the foregoing embodiment of the invention, the trenches are then filled with a filling material and contacts are formed on the surface of the semiconductor material body that are in electrical contact with the deep conductive regions.

In accordance with another embodiment of the invention, the process for manufacturing deep well junctions includes, in succession, on a first substrate having a first conductivity type and a first doping level, growing an epitaxial layer having the first conductivity type and a second doping level lower than the first doping level; and isotropically etching the epitaxial layer using a mask to form trenches; forming deep conductive regions surrounding the trenches and having a second conductivity type opposite to the first conductivity type and the second doping level; and filling the trenches. Ideally, the deep conductive regions are formed by angular ionic implantation and subsequent diffusion of a doping ion species within the epitaxial layer.

### BRIEF DESCRIPTION OF THE DRAWINGS

In order to assist understanding of the invention, an embodiment is now described purely by way of non-limiting example, and with reference to the attached drawings, wherein:

FIGS. 1-6 show cross-sections of a wafer of semiconductor material, in successive manufacture steps, carried out according to the present invention;

FIG. 7 shows the plot of quantities relative to a junction structure formed using the process according to the present invention; and

FIGS. 8-12 show cross-sections of a wafer of semiconductor material, in successive manufacture steps, in which a device comprising a junction structure according to the present invention is formed.

### DETAILED DESCRIPTION OF THE INVENTION

With reference to FIGS. 1-6, a wafer 1 of semiconductor material, for example monocrystalline silicon, comprises a substrate 2 of N+ type, with a first doping level, for example, of 10¹⁹ atoms/cm³.

An epitaxial layer 3O is initially grown (FIG. 1) in the substrate 2, and has a second doping level, lower than the first doping level, for example, of 10¹⁵ atoms/cm³. In addition, the epitaxial layer 3 has a thickness comprised preferably between 20 μm and 100 μm.

On top of the epitaxial layer 3, a trench mask 5 is then formed, and covers the entire surface 6 of the substrate 2, except at apertures 8 (FIG. 2). These apertures 8 have a first width L1, comprised preferably between 1 μm and 5 μm, and are spaced from one another by a predetermined distance (for example 10-30 μm). In order to form the trench mask 5, thermal oxidation of the substrate 2 for example is firstly carried out, and silicon oxide is then deposited. A resist mask 9 is then formed through a photolithographic process, and selective etching of the silicon oxide exposed is carried out, to form the apertures 8. The resist mask 9 is then removed.

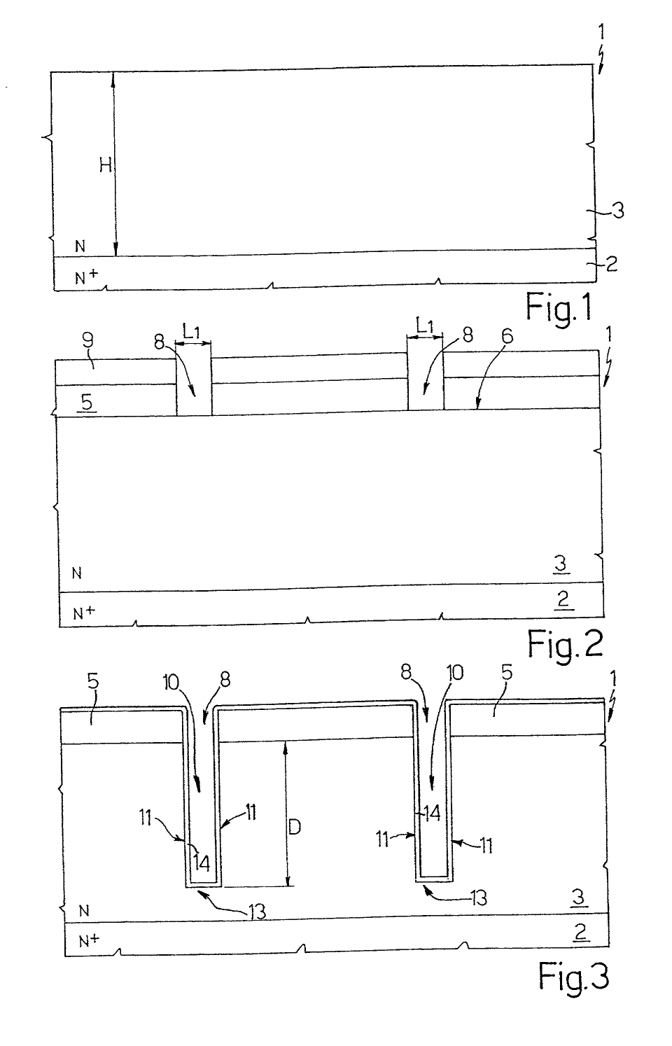

As shown in FIG. 3, an anisotropic etch of the epitaxial layer 3 (trench etch of the silicon) is then carried out, in order to form trenches 10, which have a width equal to the first width L1, and have lateral walls 11 that are substantially vertical, and extend at apertures 8, for a pre-determined depth D. In particular, the depth D of the trenches 10 is selected on the basis of the inverse breakdown voltage to be obtained, in a manner known to persons skilled in the art, and is generally slightly less than the thickness of the epitaxial layer 3, such that the trenches 10 extend as far as near the substrate 2. In addition, the trench etch is preferably a dry, plasma etch.

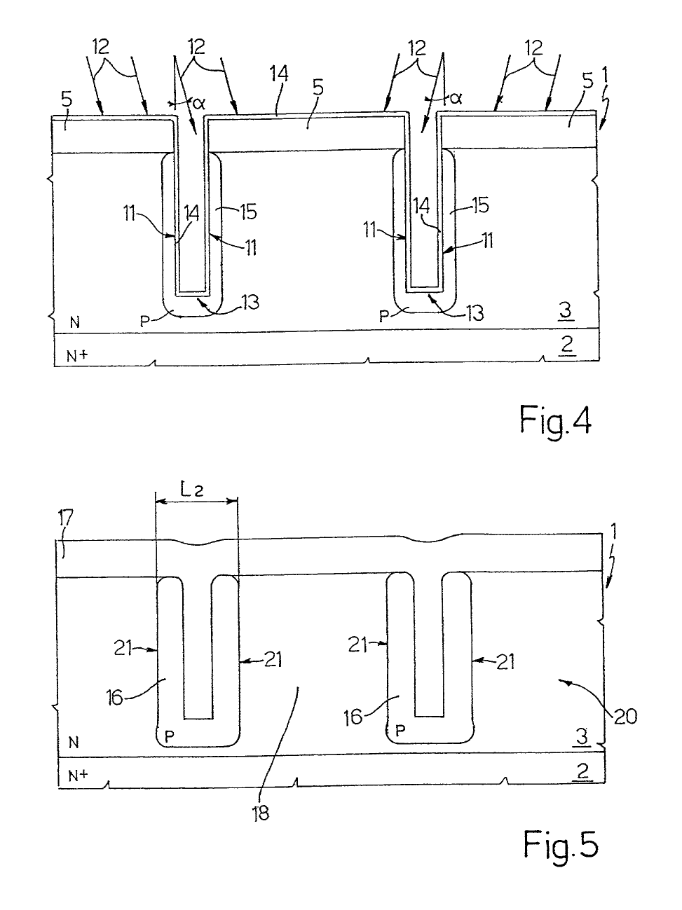

By thermal oxidation, a pre-implant oxide layer 14 is then formed, which covers the vertical walls 11 and the base walls 13 of the trenches 10, and has a thickness of, for example, 150-500 nm, as shown in FIG. 4.

Subsequently, a predetermined quantity of a doping ion species (for example boron) is implanted, as represented schematically in FIG. 4 through arrows 12. The quantity of implanted ion species is selected such that, subsequently, regions are formed (deep wells 16 in FIG. 5), which have a substantially same doping level as the second doping level of the epitaxial layer 3 (approximately 10¹⁵ atoms/cm³).

In this step, the wafer is rotated such that the implantation takes place along directions inclined by an angle α with respect to the perpendicular to the surface 6 of the epitaxial layer 3. In particular, this can be obtained by tilting the wafer 1 by an angle α with respect to a plane perpendicular to the implantation direction (arrows 12), and then rotating the wafer 1.

The angle α depends on the ratio between the width L1 of the apertures 8 and the depth D of the trenches 10, and is such that the doping ion species is implanted both on the lateral walls 11, and on the base walls 13 of the trenches 10. Thus, implanted regions 15 are formed, which surround the trenches 10, and have a conductivity opposite to the epitaxial layer 3 (for example P type conductivity).

Subsequently, as shown in FIG. 5, the implanted ion species is diffused in an inert environment, so that, on the basis of the implanted regions 15, deep wells 16 are formed, which have a second width L2, preferably between 5 μm and 20 μm, and are separated from one another by intermediate zones 18 of the epitaxial layer 3 (with a width comprised between 10 μm and 20 μm).

The trench mask 5 is then removed, and the trenches 10 are filled, as illustrated in FIG. 5. In particular, the trenches 10 are filled by depositing a thick oxide layer 17 (for example TEOS—TetraEthylOrthoSilicate).

Now, a junction structure 20 is formed, comprising the epitaxial layer 3 and the deep wells 16. In detail, interface regions 21 between the deep wells 16 and the epitaxial layer 3 form PN junctions, which extend substantially at right-angles to the surface 6 of the epitaxial layer 3.

The deep wells 16 can have different shapes, for example the shape of a cup (such as to have a circular crown or polygonal shape in plan view), or they can form elongate trenches, which extend in parallel, in a direction perpendicular to the plane of the plate.

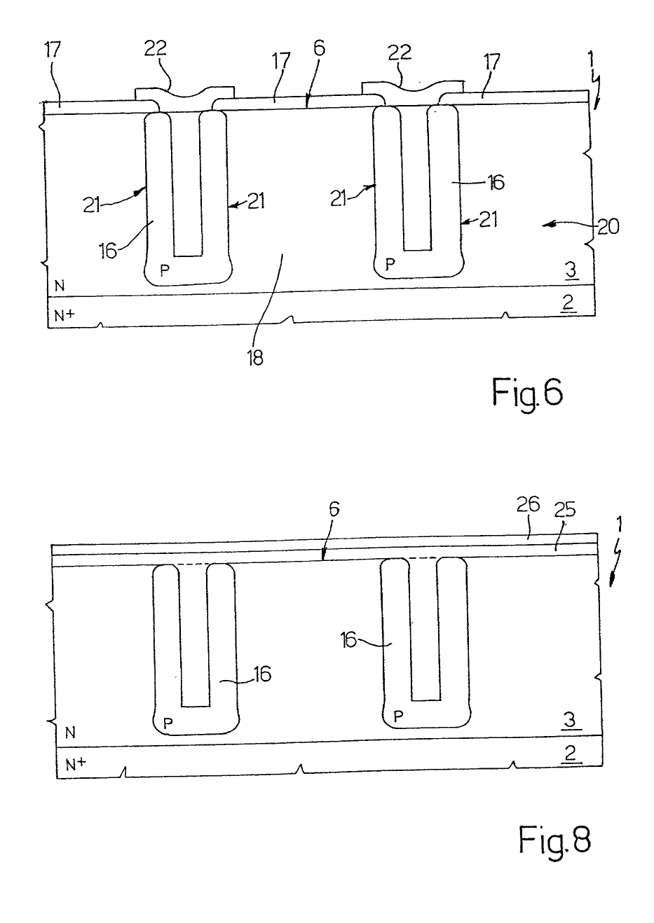

With reference to FIG. 6, the process can be completed by further, known, processing steps, comprising for example partial removal of the thick oxide layer 17 on top of the deep wells 16 (etch back), and metallization, in order to form contacts 22.

It is apparent from the foregoing description that the method according to the present invention advantageously allows junction structures to be formed with deep wells, using a limited number of processing steps. In particular, it is sufficient to carry out a single photolithographic process (for defining the trench mask 5), and a single ionic implant.

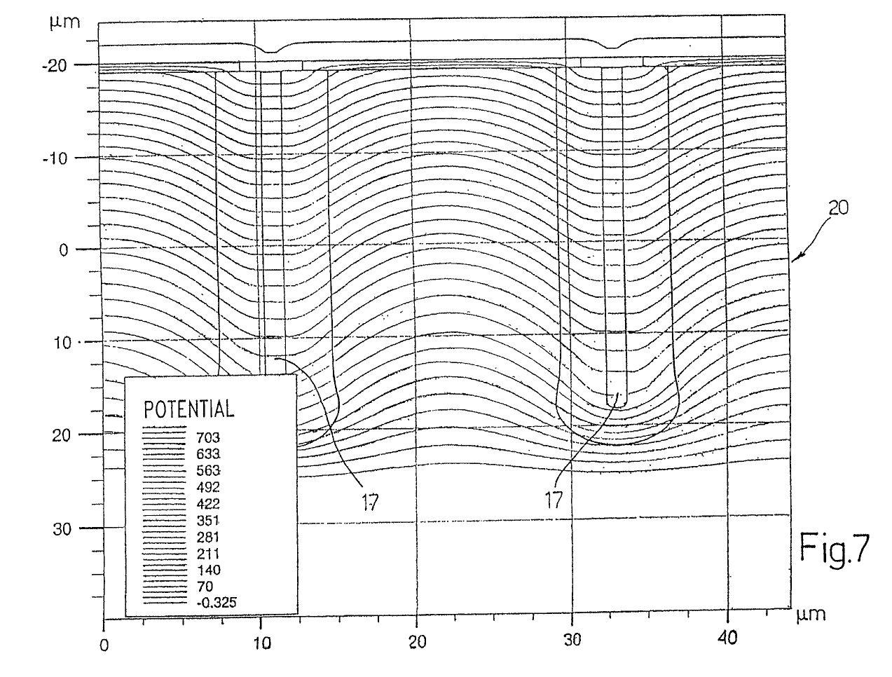

The used processing steps are also of a standard type, and thus the process, which is simple and economical to carry out, yields, with a high output, junction structures with high performance levels. In particular, FIG. 7, relative to experimental tests carried out on a junction structure formed according to the invention, shows that the presence of dielectric (silicon oxide region 17) within the deep wells 16 does not affect the distribution of the electrical field lines, in presence of strong inverse biasing (750 V).

The described process can advantageously be used to form power devices, for example DMOS transistors with a vertical current flow. In this case, when the junction structure 20 in FIG. 5 has been obtained, the portion of the thick oxide layer 17 which projects from the trenches 10 is removed, for example using a chemical-mechanical action (CMP—Chemical-Mechanical Polishing), and a gate oxide layer 25 is thermally grown and covers the surface 6 of the epitaxial layer 3, FIG. 8. A conductive layer 26, for example of polycrystalline silicon, is then deposited on top of the gate oxide layer 25.

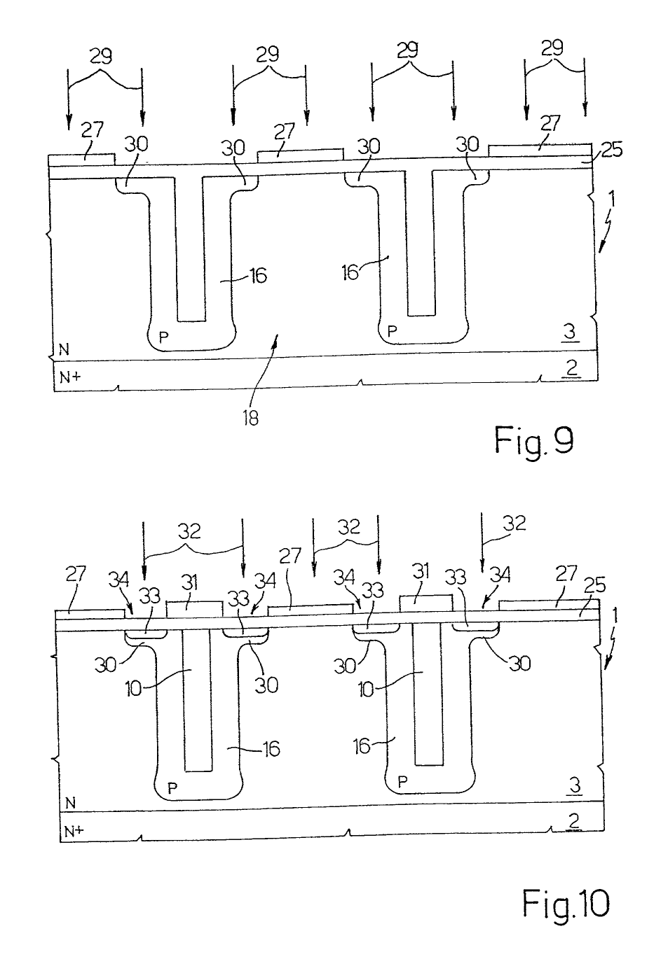

Through a photolithographic process and a subsequent chemical etch, portions of the conductive layer 26 are selectively removed, such as to define gate regions 27, extending over respective intermediate zones 18 of the epitaxial layer 3, as shown in FIG. 9.

Then a doping ion species of P type, for example boron, is implanted, as indicated schematically here through arrows 29, such as to form first enriched regions 30, of P+ type.

Subsequently, a resist mask 31 is formed over the trenches 10 and extends in part laterally to the same trenches (FIG. 10). Thereby, implant windows 34 are defined between the resist mask 31 and the gate regions 27.

A doping ion species of N type, for example phosphorous, is then implanted, as indicated here schematically through arrows 32, to form second enriched regions 33 of N+ type, at the implant windows 34.

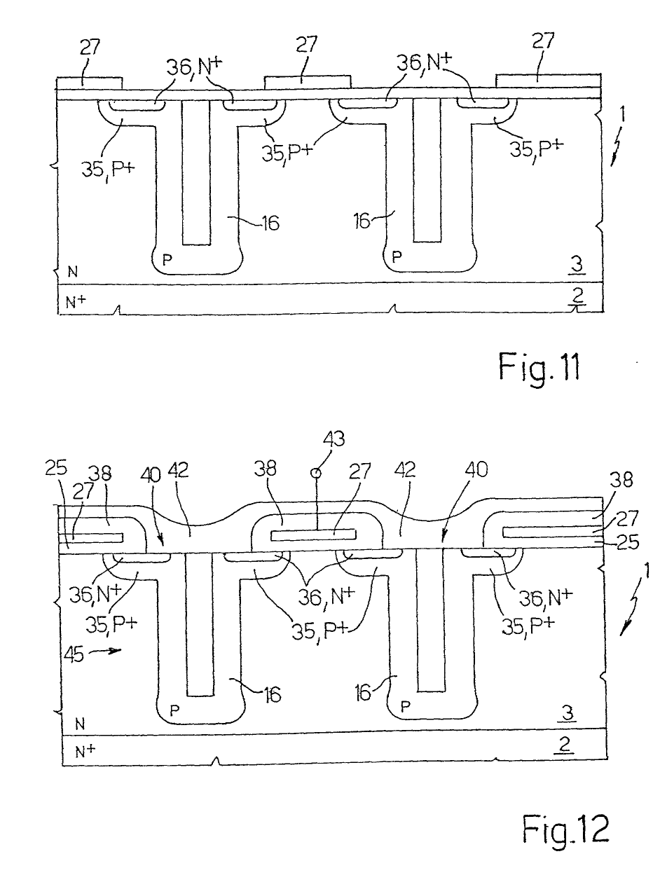

With reference to FIG. 11, the resist mask 31 is removed, and the implanted doping species are diffused. In detail, exploiting the different diffusion speeds of the P and N type species, body regions 35 of P+ type, and source regions 36 of N+ type are formed starting respectively from the first and second enriched regions 30, 33. By virtue of the diffusion process, the body regions 35 extend partially below the gate regions 27.

Subsequently (FIG. 12), an oxide layer 38 (for example VAPOX—Vapor Oxide) is formed on top of the entire wafer 1, and is then selectively etched to open contact windows 40 and uncover adjacent portions of the body regions 35 and source regions 36.

Source contacts 42 are then formed using a metallization step. These source contacts 42 fill the contact windows 40, and reach both the body regions 35 and the source regions 36.

Finally, a gate contact 43, shown here only schematically, is formed, and an MOS power transistor 45 is completed.

Finally, it is apparent that modifications and variants can be made to the described process, without departing from the scope of the present invention. For example, any suitable material can be used to fill the trenches 10, including a non-isolating material; in addition, the conductivity of the active layers can be opposite that described. Thus, the invention is to be limited only by the claims appended hereto and the equivalents thereof.

1. A process for manufacturing deep well junction structures, comprising:
in a semiconductor material body having a first conductivity type, forming trenches having a depth and a first width;
forming deep conductive regions surrounding said trenches and having a second conductivity type, opposite to said first conductivity type, said deep conductive regions extending from said trenches towards the interior of said semiconductor material body; and
filling said trenches with filling material.

2. The process of claim 1, wherein said forming deep conductive regions comprises:
implanting a doping species along directions inclined with respect to a perpendicular to a surface of said semiconductor material body; and
diffusing said doping species.

3. The process of claim 2, comprising, before forming said trenches:
growing an epitaxial layer on top of a substrate of semiconductor material, said substrate having said first conductivity type and a first doping level, said epitaxial layer having said first conductivity type and a second doping level, lower than said first doping level.

4. The process of claim 3, wherein the deep conductive regions have approximately said second doping level.

5. The process of claim 4, wherein the second doping level is comprised between 10¹⁴ and 10¹⁶ atoms/cm³.

6. The process of claim 2, wherein forming trenches comprises carrying out a masked anisotropic etch of said semiconductor material body.

7. The process of claim 6, wherein the anisotropic etch is a plasma etch.

8. The process of claim 2, wherein the filling material is a dielectric material.

9. The process of claim 8, wherein filling said trenches comprises depositing said dielectric material.

10. The process of claim 8, wherein the dielectric material is silicon oxide.

11. The process of claim 2, wherein the first width of said trenches is between 1 μm and 5 μm.

12. The process of claim 2, wherein each of the deep conductive regions is well-shaped and has a second width comprised between 5 μm and 20 μm, and the deep conductive regions are spaced from one another by 10 μm to 20 μm.

13. The process of claim 2, wherein the first conductivity type is N type, and said second conductivity type is P type.

14. A process for manufacturing DMOS transistors, comprising:
in a semiconductor material body having a first conductivity type, forming trenches having a depth and a width;
forming deep conductive regions surrounding said trenches and having a second conductivity type, opposite to said first conductivity type, said deep conductive regions extending from said trenches towards the interior of said semiconductor material body;
filling said trenches with filling material;
forming gate regions on top of said semiconductor material body, between adjacent pairs of deep conductive regions;
forming body regions in said semiconductor material body, close to a surface of said semiconductor material body, said body regions being adjacent and in electrical contact with said deep conductive regions, and extending partially below said gate regions; and
forming source regions within said body regions, facing said surface, laterally with respect to said gate regions.

15. The process of claim 14, wherein forming deep conductive regions comprises:
implanting a doping species along directions inclined with respect to a perpendicular to a surface of the semiconductor material body.

16. A process for manufacturing deep well junction structures, comprising:
forming at least one trench in a semiconductor material body having a first conductivity type; and
forming a deep conductive region surrounding the at least one trench and having a second conductivity type opposite to the first conductivity type, the deep conductive region formed by angular ionic implantation.

17. The process of claim 16, further comprising subsequent diffusion of a doping ion species within an epitaxial layer on the semiconductor material body after the angular ionic implantation.

18. A process for manufacturing deep well junction structures, comprising:
growing an epitaxial layer on a first substrate of a first conductivity type and a first doping level, the epitaxial layer having the first conductivity type and a second doping level lower than the first doping level;
anisotropically etching the epitaxial layer using a mask to form at least one trench;
forming a deep conductive region surrounding the at least one trench and having a second conductivity type opposite to the first conductivity type and to the second doping level by angular ionic implantation and subsequent diffusion of a doping ion species within the epitaxial layer; and
filling the trenches with a filling material.

19. A process for manufacturing DMOS transistors, comprising:
in a semiconductor material body having a first conductivity type, forming trenches having a depth and a width;
forming deep conductive regions surrounding the trenches and having a second conductivity type opposite to the first conductivity type by implanting a doping species along directions inclined with respect to a perpendicular to a surface of the semiconductor material body, the deep conductive regions extending from the trenches towards the interior of the semiconductor material body;
filling said trenches with filling material;
forming gate regions on top of said semiconductor material body and between adjacent pairs of deep conductive regions;
forming body regions in said semiconductor material body, close to a surface of said semiconductor material body, said body regions being adjacent and in electrical contact with said deep conductive regions, and extending partially below said gate regions; and
forming source regions within said body regions, facing said surface, laterally with respect to said gate regions.

20. The process of claim 19, wherein forming deep conductive regions comprises rotating the semiconductor material body about an axis that is oriented an angle with respect to a plane perpendicular to the implant direction.
